(19) United States
(12) Patent Application Publication
(10) Pub. No.: US 2026/0213131 A1
(43) Pub. Date: Jul. 23, 2026

(54) PLASMA PROCESSING APPARATUS

(71) Applicant: Tokyo Electron Limited, Tokyo (JP)

(72) Inventor: Natsumi TORII, Miyagi (JP)

(73) Assignee: Tokyo Electron Limited, Tokyo (JP)

(21) Appl. No.: 19/571,522

(22) Filed: Mar. 19, 2026

Related U.S. Application Data
(63) Continuation of application No. PCT/JP2024/025501, filed on Jul. 16, 2024.

(30) Foreign Application Priority Data
Sep. 29, 2023 (JP) 2023-169603

(51) Int. Cl. H01J 37/32

(52) U.S. Cl. CPC H01J 37/32183; H01J 37/32091; H01J 37/32146

(57) ABSTRACT

A plasma processing apparatus including a chamber; a substrate support disposed in the chamber and including at least one lower electrode; an upper electrode; an RF signal generator electrically connected to the at least one lower electrode or the upper electrode, and generating an RF signal for generating a plasma in the chamber; a first voltage signal generator electrically connected to the at least one lower electrode and generating a first voltage signal, the first voltage signal having a sequence of first voltage pulses; a second voltage signal generator electrically connected to the upper electrode and generating a second voltage signal; a capacitor; and a rectifying element including a first electrode and a second electrode, the first electrode being electrically connected to a node between the upper electrode and the second voltage signal generator, and the second electrode being electrically connected to a ground potential via the capacitor.

### CROSS-REFERENCE TO RELATED APPLICATIONS

This application is a Continuation of PCT International Application No. PCT/JP2024/025501, filed on Jul. 16, 2024, which claims priority under 35 U.S.C. §119(a) to Japanese Patent Application No. 2023-169603, filed in Japan on Sep. 29, 2023, all of which are hereby expressly incorporated by reference into the present application.

### BACKGROUND

An exemplary embodiment of the present disclosure relates to a plasma processing apparatus.

JP2015-5755 A discloses a direct current power supply for applying a negative direct current voltage to an upper electrode. US 2022/0037119 A1 discloses a voltage pulse generator for applying a negative voltage pulse to a bias electrode of a substrate support.

### SUMMARY

In one exemplary embodiment of the present disclosure, there is provided a plasma processing apparatus including a chamber; a substrate support disposed in the chamber and including at least one lower electrode; an upper electrode disposed above the substrate support; an RF signal generator electrically connected to the at least one lower electrode or the upper electrode, and configured to generate an RF signal for generating a plasma in the chamber; a first voltage signal generator electrically connected to the at least one lower electrode and configured to generate a first voltage signal, the first voltage signal having a sequence of first voltage pulses; a second voltage signal generator electrically connected to the upper electrode and configured to generate a second voltage signal; a capacitor; and a rectifying element including a first electrode and a second electrode, the first electrode being electrically connected to a node between the upper electrode and the second voltage signal generator, and the second electrode being electrically connected to a ground potential via the capacitor.

### BRIEF DESCRIPTION OF DRAWINGS

FIG. 1 is a diagram for describing a configuration example of a plasma processing system.

FIG. 2 is a diagram for describing a configuration example of a capacitively coupled plasma processing apparatus.

FIG. 3 is a diagram illustrating a coupling example between a power supply 30 and a chamber 10.

FIG. 4A is a timing chart illustrating an example of voltage waveforms of a first DC signal and a second DC signal.

FIG. 4B is a timing chart illustrating an example of voltage waveforms of the first DC signal and the second DC signal.

FIG. 4C is a timing chart illustrating an example of the voltage waveforms of the first DC signal and the second DC signal.

FIG. 4D is a timing chart illustrating an example of the voltage waveforms of the first DC signal and the second DC signal.

FIG. 5 is a diagram illustrating a configuration example of a plasma stabilizing circuit according to a first embodiment.

FIG. 6A is a diagram illustrating an example of a first filter.

FIG. 6B is a diagram illustrating an example of a second filter.

FIG. 7A is a diagram illustrating another placement example of a node N1.

FIG. 7B is a diagram illustrating another placement example of the node N1.

FIG. 8A is a diagram for describing an operation of a plasma stabilizing circuit 70.

FIG. 8B is a diagram for describing the operation of the plasma stabilizing circuit 70.

FIG. 9A is a diagram for describing a rectification operation of a first rectifying element D1.

FIG. 9B is a diagram for describing the rectification operation of the first rectifying element D1.

FIG. 10 is a diagram illustrating a configuration example of a plasma stabilizing circuit according to a second embodiment.

FIG. 11 is a diagram illustrating an example of a second rectifying element.

FIG. 12 is a diagram illustrating an example of the second rectifying element.

FIG. 13 is a diagram illustrating another coupling example between the power supply 30 and the chamber 10.

FIG. 14 is a diagram illustrating a configuration example of a plasma stabilizing circuit according to a third embodiment.

FIG. 15A is a diagram illustrating a modification example of the first embodiment.

FIG. 15B is a diagram illustrating a modification example of the second embodiment.

FIG. 16 is a diagram illustrating an example of a polarity switching circuit.

FIG. 17 is a diagram illustrating another coupling example between the power supply 30 and the chamber 10.

FIG. 18 is a diagram illustrating another coupling example between the power supply 30 and the chamber 10.

FIG. 19 is a diagram illustrating another coupling example between the power supply 30 and the chamber 10.

### DETAILED DESCRIPTION

Hereinafter, each embodiment according to the present disclosure will be described.

In one exemplary embodiment, there is provided a plasma processing apparatus including a chamber; a substrate support placed in the chamber and including at least one lower electrode; an upper electrode placed above the substrate support; an RF signal generator electrically connected to any of the at least one lower electrode or the upper electrode, and configured to generate an RF signal for generating a plasma in the chamber; a first voltage signal generator electrically connected to any of the at least one lower electrode and configured to generate a first voltage signal, the first voltage signal having a sequence of first voltage pulses; a second voltage signal generator electrically connected to the upper electrode and configured to generate a second voltage signal; a capacitor; and a rectifying element including a first electrode and a second electrode, the first electrode being electrically connected to a node between the upper electrode and the second voltage signal generator, and the second electrode being electrically connected to a ground potential via the capacitor. For elements described as being “placed” for the entire specification, these elements may also be “disposed,” already present or connected to the corresponding element/component recited.

In one exemplary embodiment, the second voltage signal has a sequence of second voltage pulses.

In one exemplary embodiment, the second voltage signal has a constant voltage level.

In one exemplary embodiment, the second voltage signal has a negative polarity, the first electrode is a cathode electrode, and the second electrode is an anode electrode.

In one exemplary embodiment, the sequence of the first voltage pulses has a first pulse frequency in a range of 0.1 MHz to 2 MHz.

In one exemplary embodiment, the sequence of the second voltage pulses has a second pulse frequency in a range of 0.1 kHz to 50 kHz.

In one exemplary embodiment, the plasma processing apparatus further includes a filter circuit provided in a transmission line between the upper electrode and the second voltage signal generator.

In one exemplary embodiment, the plasma processing apparatus further includes a filter circuit provided in a transmission line between the upper electrode and the node.

In one exemplary embodiment, the plasma processing apparatus further includes a filter circuit provided in a transmission line between the node and the second voltage signal generator.

In one exemplary embodiment, the plasma processing apparatus further includes a first filter provided in a transmission line between the upper electrode and the node, and configured to filter a signal in a band of an RF frequency of the RF signal; and a second filter provided in a transmission line between the node and the second voltage signal generator, and configured to filter a signal in a band of a pulse frequency of the sequence of the first voltage pulses.

In one exemplary embodiment, there is provided a plasma processing apparatus including: a chamber; a substrate support placed in the chamber and including at least one lower electrode; an upper electrode placed above the substrate support; an RF signal generator electrically connected to any of the at least one lower electrode or the upper electrode, and configured to generate an RF signal for generating a plasma in the chamber; a voltage signal generator electrically connected to any of the at least one lower electrode and configured to generate a voltage signal, the voltage signal having a sequence of voltage pulses; an impedance fixing circuit electrically connected to the upper electrode; a capacitor; and a rectifying element including a first electrode and a second electrode, the first electrode being electrically connected to a node between the upper electrode and the impedance fixing circuit, and the second electrode being electrically connected to a ground potential via the capacitor.

In one exemplary embodiment, the voltage pulses have a negative polarity, the first electrode is a cathode electrode, and the second electrode is an anode electrode.

In one exemplary embodiment, the sequence of the voltage pulses has a first pulse frequency in a range of 0.1 MHz to 2 MHz.

In one exemplary embodiment, the impedance fixing circuit includes at least one of a capacitor and an inductor.

In one exemplary embodiment, there is provided a plasma processing apparatus including: a chamber; a substrate support placed in the chamber and including an electrode; a first voltage signal generator electrically connected to the electrode and configured to generate a first voltage signal, the first voltage signal having a sequence of first voltage pulses; a conductive member constituting a part of the chamber or placed in the chamber; a capacitor; and a rectifying element including a first electrode and a second electrode, the first electrode being electrically connected to the conductive member, and the second electrode being electrically connected to a ground potential via the capacitor.

In one exemplary embodiment, the plasma processing apparatus further includes a second voltage signal generator electrically connected to a node between the conductive member and the first electrode of the rectifying element and configured to generate a second voltage signal.

In one exemplary embodiment, the plasma processing apparatus further includes an impedance fixing circuit electrically connected to a node between the conductive member and the first electrode of the rectifying element.

In one exemplary embodiment, the impedance fixing circuit includes at least any one of a capacitor or an inductor.

In one exemplary embodiment, the conductive member is any one of (a) an upper electrode placed above the substrate support, (b) a ring assembly placed on the substrate support to surround a substrate on the substrate support, (c) a liner placed along an inner wall of the chamber, and (d) a baffle plate placed to surround the substrate support.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### Configuration Example of Plasma Processing System

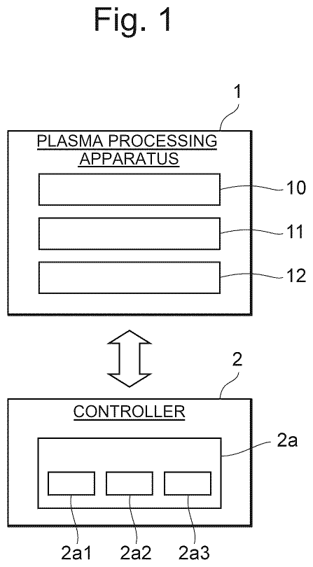

FIG. 1 is a diagram for describing a configuration example of a plasma processing system. In an embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. In addition, the plasma processing chamber 10 has at least one gas supply port for supplying at least one processing gas to the plasma processing space and at least one gas exhaust port for exhausting the gas from the plasma processing space. The gas supply port is connected to a gas supply 20, described later, and the gas exhaust port is connected to an exhaust system 40 described later. The substrate support 11 is placed in the plasma processing space and has a substrate support surface for supporting a substrate.

The plasma generator 12 is configured to generate a plasma from at least one processing gas supplied into the plasma processing space. The plasma generated in the plasma processing space may be a capacitively coupled plasma (CCP), an inductively coupled plasma (ICP), an electron-cyclotron-resonance plasma (ECR plasma), a helicon wave plasma (HWP), a surface wave plasma (SWP), or the like. Further, various types of plasma generators including an alternating current (AC) plasma generator and a direct current (DC) plasma generator may be used. In an embodiment, an AC signal (AC power) used in the AC plasma generator has a frequency in the range of 100 kHz to 10 GHz. Therefore, the AC signal includes a radio frequency (RF) signal and a microwave signal. In an embodiment, the RF signal has a frequency in the range of 100 kHz to 150 MHz.

The controller 2 processes a computer-executable instruction that causes the plasma processing apparatus 1 to execute various steps described in the present disclosure. The controller 2 may be configured to control each element of the plasma processing apparatus 1 to execute the various steps described here. In an embodiment, a part or the entirety of the controller 2 may be included in the plasma processing apparatus 1. The controller 2 may include a processor 2a1, a storage 2a2, and a communication interface 2a3. The controller 2 is realized by, for example, a computer 2a. The processor 2a1 may be configured to read out a program from the storage 2a2 and to execute the read-out program to perform various control operations. This program may be stored in the storage 2a2 in advance, or may be acquired via a medium when necessary. The acquired program is stored in the storage 2a2, is read out from the storage 2a2, and is executed by the processor 2a1. The medium may be various storage media readable by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

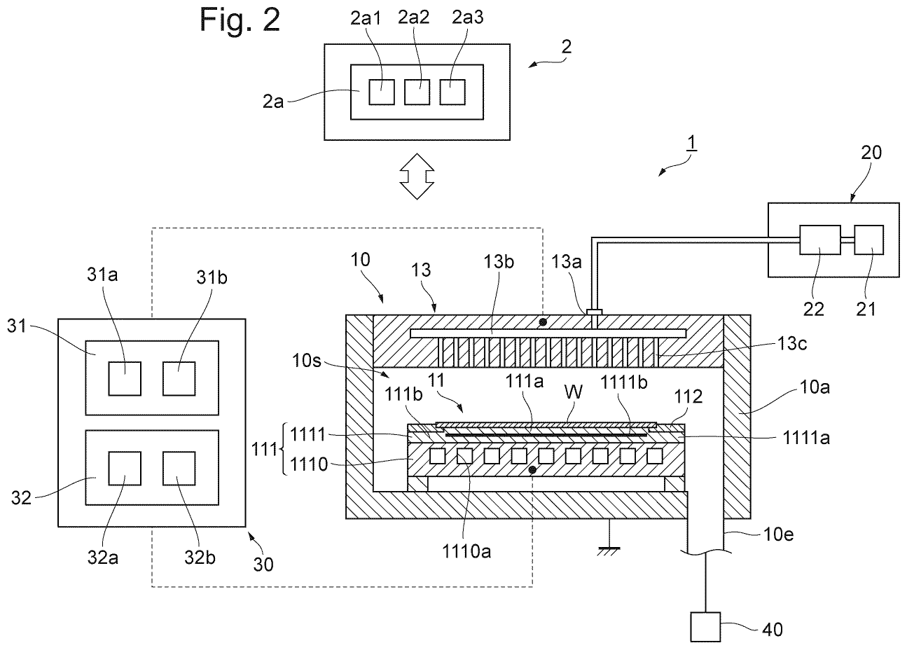

Hereinafter, a configuration example of the capacitively coupled plasma processing apparatus as an example of the plasma processing apparatus 1 will be described. FIG. 2 is a diagram for describing a configuration example of the capacitively coupled plasma processing apparatus.

The capacitively coupled plasma processing apparatus 1 includes the plasma processing chamber 10, the gas supply 20, a power supply 30, and the exhaust system 40. In addition, the plasma processing apparatus 1 includes a substrate support 11 and a gas introducer. The gas introducer is configured to introduce at least one processing gas into the plasma processing chamber 10. The gas introducer includes a shower head 13. The substrate support 11 is placed in the plasma processing chamber 10. The shower head 13 is placed above the substrate support 11. In an embodiment, the shower head 13 constitutes at least a part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a center region 111a for supporting a substrate W and an annular region 111b for supporting the ring assembly 112. A wafer is an example of the substrate W. The annular region 111b of the main body 111 surrounds the center region 111a of the main body 111 in plan view. The substrate W is placed on the center region 111a of the main body 111, and the ring assembly 112 is placed on the annular region 111b of the main body 111 to surround the substrate W on the center region 111a of the main body 111. Therefore, the center region 111a is also referred to as a substrate support surface for supporting the substrate W, and the annular region 111b is also referred to as a ring support surface for supporting the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 is placed on the base 1110. The electrostatic chuck 1111 includes a ceramic member 1111a and an electrostatic electrode 1111b placed in the ceramic member 1111a. The ceramic member 1111a has the center region 111a. In an embodiment, the ceramic member 1111a also has the annular region 111b. Another member that surrounds the electrostatic chuck 1111 may have the annular region 111b, such as an annular electrostatic chuck or an annular insulating member. In this case, the ring assembly 112 may be placed on the annular electrostatic chuck or the annular insulating member, or may be placed on both the electrostatic chuck 1111 and the annular insulating member. Further, at least one RF/DC electrode coupled to an RF power supply 31 and/or a DC power supply 32, which will be described later, may be placed in the ceramic member 1111a. In this case, at least one RF/DC electrode functions as the lower electrode. When a bias RF signal and/or a DC signal, which will be described later, are supplied to at least one RF/DC electrode, the RF/DC electrode is also referred to as a bias electrode. The conductive member of the base 1110 and at least one RF/DC electrode may function as the multiple lower electrodes. Further, the electrostatic electrode 1111b may function as the lower electrode. Therefore, the substrate support 11 includes at least one lower electrode.

The ring assembly 112 includes one or multiple annular members. In an embodiment, one or the multiple annular members includes one or multiple edge rings and at least one cover ring. The edge ring is formed of a conductive material or an insulating material, and the cover ring is formed of an insulating material.

In addition, the substrate support 11 may include a temperature-controlled module configured to adjust at least one of the electrostatic chuck 1111, the ring assembly 112, and the substrate to a target temperature. The temperature-controlled module may include a heater, a heat transfer medium, a flow passage 1110a, or a combination thereof. A heat transfer fluid such as brine or a gas flows in the flow passage 1110a. In an embodiment, the flow passage 1110a is formed in the base 1110, and one or multiple heaters is placed in the ceramic member 1111a of the electrostatic chuck 1111. Further, the substrate support 11 may include a heat transfer gas supply configured to supply a heat transfer gas to a gap between a back surface of the substrate W and the center region 111a.

The shower head 13 is configured in such a manner that at least one processing gas is introduced from the gas supply 20 into the plasma processing space 10s. The shower head 13 has at least one gas supply port 13a, at least one gas diffusion chamber 13b, and multiple gas introduction ports 13c. The processing gas supplied to the gas supply port 13a passes through the gas diffusion chamber 13b and is introduced into the plasma processing space 10s from the multiple gas introduction ports 13c. In addition, the shower head 13 includes at least one upper electrode. In addition to the shower head 13, the gas introducer may include one or multiple side gas injectors (SGI) attached to one or multiple opening portions formed on the side wall 10a.

The gas supply 20 may include at least one gas source 21 and at least one flow rate controller 22. In an embodiment, the gas supply 20 is configured to supply at least one processing gas to the shower head 13 from each corresponding gas source 21 via each corresponding flow rate controller 22. Each flow rate controller 22 may include, for example, a mass flow controller or a pressure-controlled flow rate controller. Further, the gas supply 20 may include at least one flow rate modulation device that modulates or pulses a flow rate of at least one processing gas.

The power supply 30 includes the RF power supply 31 coupled to the plasma processing chamber 10 via at least one impedance matching circuit. The RF power supply 31 is configured to supply at least one RF signal (RF power) to at least one lower electrode and/or at least one upper electrode. As a result, the plasma is generated from at least one processing gas supplied to the plasma processing space 10s. Therefore, the RF power supply 31 may function as at least a part of the plasma generator 12. Further, by supplying the bias RF signal to at least one lower electrode, a bias potential is generated in the substrate W, and an ion component in the generated plasma is able to be drawn into the substrate W.

In an embodiment, the RF power supply 31 includes a first RF generator 31a and a second RF generator 31b. The first RF generator 31a is coupled to at least one lower electrode and/or at least one upper electrode via at least one impedance matching circuit and is configured to generate a source RF signal (source RF power) for plasma generation. In an embodiment, the source RF signal has a frequency in the range of 10 MHz to 150 MHz. In an embodiment, the first RF generator 31a may be configured to generate multiple source RF signals having different frequencies. The generated one or multiple source RF signals are supplied to at least one lower electrode and/or at least one upper electrode.

The second RF generator 31b is coupled to at least one lower electrode via at least one impedance matching circuit and is configured in such a manner that the bias RF signal (bias RF power) is generated. The frequency of the bias RF signal may be the same as or different from the frequency of the source RF signal. In an embodiment, the bias RF signal has a frequency lower than the frequency of the source RF signal. In an embodiment, the bias RF signal has a frequency in the range of 100 kHz to 60 MHz. In an embodiment, the second RF generator 31b may be configured to generate multiple bias RF signals having different frequencies. The generated one or multiple bias RF signals are supplied to at least one lower electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes a first DC generator 32a and a second DC generator 32b. In an embodiment, the first DC generator 32a is connected to at least one lower electrode, and is configured to generate a first DC signal. The generated first DC signal is applied to at least one lower electrode. In an embodiment, the second DC generator 32b is connected to at least one upper electrode and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulse may have a pulse waveform having a rectangular shape, a trapezoidal shape, a triangular shape, or a combination thereof. In an embodiment, a waveform generator for generating the sequence of voltage pulses from the DC signal is connected between the first DC generator 32a and at least one lower electrode. Therefore, the first DC generator 32a and the waveform generator constitute a voltage pulse generator. When the second DC generator 32b and the waveform generator constitute the voltage pulse generator, the voltage pulse generator is connected to at least one upper electrode. The voltage pulse may have a positive polarity or a negative polarity. In addition, the sequence of voltage pulses may include one or multiple positive voltage pulses and one or multiple negative voltage pulses in one cycle. The first and second DC generators 32a and 32b may be provided in addition to the RF power supply 31, or the first DC generator 32a may be provided instead of the second RF generator 31b.

The exhaust system 40 may be connected to, for example, a gas exhaust port 10e provided at a bottom portion of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

### Coupling Example between Power Supply 30 and Plasma Processing Chamber 10

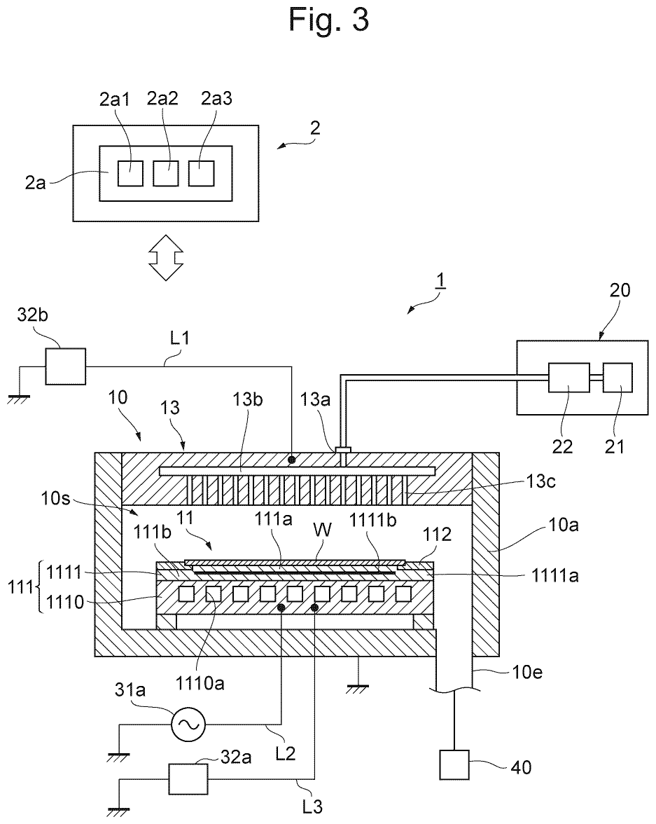

FIG. 3 is a diagram illustrating a coupling example between the power supply 30 and the plasma processing chamber 10 (hereinafter, also referred to as the “chamber 10”) of the plasma processing apparatus 1.

In an embodiment, the first RF generator 31a is electrically connected to the lower electrode of the substrate support 11 via a transmission line L2. One or multiple lower electrodes may be provided in the substrate support 11. When multiple lower electrodes are provided, the first RF generator 31a may be electrically connected to any one of the multiple lower electrodes. At least one impedance matching circuit is provided in the transmission line L2. The first RF generator 31a is configured to generate the source RF signal for plasma generation. In an embodiment, the source RF signal has a frequency in the range of 10 MHz to 150 MHz. In an embodiment, the first RF generator 31a may be configured to generate multiple source RF signals having different frequencies. In an embodiment, the first RF generator 31a may be electrically connected to the upper electrode via at least one impedance matching circuit. In this case, only one lower electrode may be provided in the substrate support (that is, multiple lower electrodes may not be provided in the substrate support).

In an embodiment, the first DC generator 32a is electrically connected to the lower electrode of the substrate support 11 via a transmission line L3. When multiple lower electrodes are provided, the first DC generator 32a may be electrically connected to the same lower electrode as the first RF generator 31a, or may be electrically connected to the lower electrode different from the first RF generator 31a. The first DC generator 32a is configured to generate the first DC signal.

In an embodiment, the first DC signal may be pulsed. For example, the first waveform generator may be provided on an output side (lower electrode side) of the first DC generator 32a. The first waveform generator generates the sequence of first voltage pulses from the first DC signal. As a result, the first voltage signal having the sequence of first voltage pulses may be applied to the lower electrode. The first voltage pulse may have a pulse waveform of a rectangular shape, a trapezoidal shape, a triangular shape, or a combination thereof. The first waveform generator may be integrally provided in the first DC generator 32a.

In an embodiment, the first DC signal may not be pulsed. For example, the first DC signal may have a constant voltage level, and the first DC signal having the constant voltage level may be applied to the lower electrode.

In an embodiment, the second DC generator 32b is electrically connected to the upper electrode of the shower head 13 via the transmission line L1. The second DC generator 32b is configured to generate the second DC signal. A rectifying element that limits a direction of a current is provided in the transmission line L1 between the second DC generator 32b and the upper electrode. Each configuration of the transmission line L1 including the rectifying element will be described later.

In an embodiment, the second DC signal may be pulsed. For example, a second waveform generator may be provided on the transmission line L1 on the output side (upper electrode side) of the second DC generator 32b. The second waveform generator generates a sequence of second voltage pulses from the second DC signal. As a result, the second DC signal having the sequence of second voltage pulses may be applied to the upper electrode. The second voltage pulse may have a pulse waveform of a rectangular shape, a trapezoidal shape, a triangular shape, or a combination thereof. The second waveform generator may be integrally provided in the second DC generator 32b.

In an embodiment, the second DC signal may not be pulsed. For example, the second DC signal may have a constant voltage level, and the second DC signal having the constant voltage level may be applied to the upper electrode.

### Example of First DC Signal and Second DC Signal

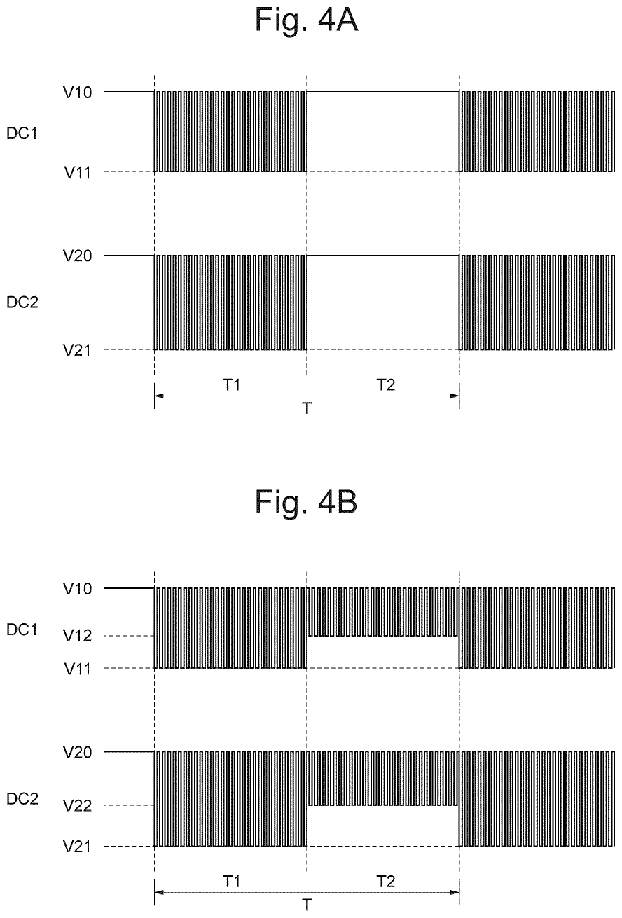

FIGS. 4A to 4D are timing charts illustrating an example of voltage waveforms of the first DC signal and the second DC signal. In an embodiment, the voltage waveforms of the first DC signal and the second DC signal may be repeated multiple times in a repeating period T (see FIGS. 4A to 4D). In an example, the first DC signal may have a repetition frequency (1/T) of 0.1 kHz to 50 kHz. In an example, the second DC signal may have a repetition frequency (1/T) of 0.1 kHz to 50 kHz. The repetition frequency of the first DC signal and the repetition frequency of the second DC signal may be the same as or different from each other. The first DC signal and the second DC signal may be synchronized (see FIGS. 4A to 4C), or may not be synchronized. For example, the first DC signal and the second DC signal may be shifted in phase by a given value (in an example, 180 degrees).

FIG. 4A is an example in which both the first DC signal (DC1) and the second DC signal (DC2) are pulsed. The first DC signal and the second DC signal may be generated by the first waveform generator and the second waveform generator, respectively. In an embodiment, the first DC signal has a sequence of first voltage pulses having a first voltage level V11 in a first period T1 in the repeating period T. In an example, the sequence of the first voltage pulses may have a pulse frequency of 0.1 MHz to 2 MHz (hereinafter, the voltage pulse having such a pulse frequency is also referred to as a “high-speed pulse”). The first DC signal has a reference voltage level V10 in a second period T2 in the repeating period T. An absolute value of the reference voltage level V10 is smaller than an absolute value of the first voltage level V11. In an embodiment, the first voltage level V11 has the negative polarity. In an embodiment, the reference voltage level V10 has a zero voltage level.

The second DC signal (DC2) has a sequence of second voltage pulses having a second voltage level V21 in the first period T1. In an example, the sequence of the second voltage pulses may have a pulse frequency of 0.1 MHz to 2 MHz. The pulse frequency of the sequence of the second voltage pulses may be the same as or different from the pulse frequency of the sequence of the first voltage pulses. In addition, the second DC signal has a reference voltage level V20 in the second period T2. The reference voltage level V20 is smaller than the absolute value of the second voltage level V21. In an embodiment, the second voltage level V21 has the negative polarity. In an embodiment, the reference voltage level V20 has a zero voltage level.

FIG. 4B is a modification example of the voltage waveform illustrated in FIG. 4A. The first DC signal (DC1) and the second DC signal (DC2) may be generated by the first waveform generator and the second waveform generator, respectively. Both the first DC signal and the second DC signal are pulsed. In this example, the first DC signal has a sequence of third voltage pulses having a third voltage level V12 in the second period T2 in the repeating period T. An absolute value of the third voltage level V12 is larger than the absolute value of the reference voltage level V10 and smaller than the absolute value of the first voltage level V11. The sequence of third voltage pulses may have a pulse frequency of 0.1 MHz to 2 MHz. In addition, the second DC signal has a sequence of fourth voltage pulses having a fourth voltage level V22 in the second period T2 in the repeating period T. An absolute value of the fourth voltage level V22 is larger than the absolute value of the reference voltage level V20 and smaller than the absolute value of the second voltage level V21. The sequence of fourth voltage pulses may have a pulse frequency of 0.1 MHz to 2 MHz. The other points are the same as the example illustrated in FIG. 4A. In the example illustrated in FIG. 4B, the repeating period T may further have a third period T3. The first DC signal may have the reference voltage level V10 in the third period T3 within the repeating period T. In addition, the second DC signal may have the reference voltage level V20 in the third period T3 in the repeating period T.

FIG. 4C is a modification example of the voltage waveform illustrated in FIG. 4A. Both the first DC signal (DC1) and the second DC signal (DC2) are pulsed. The first DC signal may be generated by the first waveform generator. The second DC signal may be generated by the second waveform generator (including a case of being integrally configured with the second DC generator 32b), or may be generated by the second DC generator 32b. In this example, the second DC signal has a sequence of second voltage pulses in the repeating period T. That is, the sequence of the second voltage pulses in this example has the second voltage level V21 in the first period T1 and has the reference voltage level V20 in the second period T2. The pulse frequency of the sequence of the second voltage pulses may be the same as the repetition frequency (1/T) of the first DC signal, and may be, for example, 0.1 kHz to 50 kHz (hereinafter, the voltage pulse having such a pulse frequency is also referred to as a “low-speed pulse”). The other points may be the same as example illustrated in FIG. 4A.

FIG. 4D is a modification example of the voltage waveform illustrated in FIG. 4A. In this example, only the first DC signal (DC1) is pulsed, and the second DC signal has a constant voltage level (second voltage level V21) in the first period T1 and the second period T2 in the repeating period T. The second DC signal may be generated by the second DC generator 32b. The other points may be the same as the example illustrated in FIG. 4A.

### First Embodiment

Immediately after the first DC signal is supplied to the lower electrode (for example, about 1 to 3 cycles of the high-speed pulse), a sudden current (hereinafter, this current is also referred to as a “transient current”) may flow through the upper electrode instantaneously. A magnitude of the transient current tends to increase as the voltage level of the first DC signal (bias signal) increases. The transient current is considered to be a current required for stabilizing the plasma in the chamber, and when the transient current is limited by the circuit configuration or the like of the power supply 30, the plasma may be destabilized. When the plasma is destabilized, for example, abnormal discharge or the like may occur in the upper electrode (for example, the gas introduction port 13c of the shower head 13 or the like). In the first embodiment, such destabilization of the plasma may be suppressed by including a plasma stabilizing circuit described below.

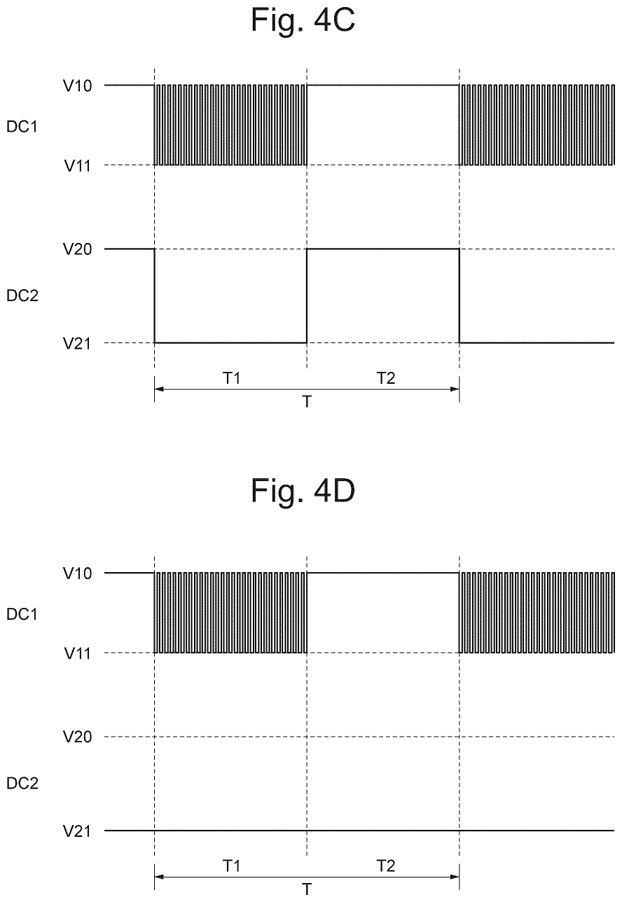

FIG. 5 is a diagram illustrating a configuration example of the plasma stabilizing circuit according to the first embodiment. The first embodiment is a configuration example of a case where a negative polarity first DC signal is supplied to the lower electrode. As illustrated in FIG. 5, a node N1 is provided on a transmission line L1 between the chamber 10 (upper electrode) and the second DC generator 32b. A first rectifying element D1 and a plasma stabilizing circuit 70 are provided on a transmission line L12 between the node N1 and the ground potential. In addition, a first filter F1 and a second filter F2 are provided on the transmission line L1 from the chamber 10 (upper electrode) toward the second DC generator 32b. In the example illustrated in FIG. 5, the node N1 is on the transmission line L1 between the first filter F1 and the second filter F2. In addition, in the example illustrated in FIG. 5, the first rectifying element D1 is provided on the transmission line L12 between the node N1 and the plasma stabilizing circuit 70. In an embodiment, the first rectifying element D1 may be provided on the transmission line L12 between the plasma stabilizing circuit 70 and the ground potential.

In an embodiment, the second DC generator 32b generates a negative polarity second DC signal. The second DC signal generated by the second DC generator 32b may have a low-speed pulse as illustrated in FIG. 4C. In addition, the second DC signal generated by the second DC generator 32b may have a constant voltage level as illustrated in FIG. 4D. The second waveform generator may not be provided. In an embodiment, the second DC generator 32b may generate a positive second DC signal.

The plasma stabilizing circuit 70 includes a capacitor C1. A capacitance of the capacitor C1 is large enough to instantaneously supply a sufficient charge to the upper electrode. In an example, the capacitance of the capacitor C1 is 10 nF to 100 nF. The capacitor C1 may be configured with one or multiple capacitors.

In an embodiment, the plasma stabilizing circuit 70 may be configured to include a resistor R as a charge removal circuit. The resistor R is connected in parallel to the capacitor C1. The resistor R may be configured to remove the charge of the capacitor C1 in about 1 to 10 seconds. As the charge removal circuit, an inductor may be used instead of or in addition to the resistor R. In addition, when the first rectifying element D1 is provided on the transmission line L12 between the plasma stabilizing circuit 70 and the ground potential, the resistor R may be connected to a node of the transmission line L12 between the capacitor C1 and the first rectifying element D1.

The plasma stabilizing circuit 70 instantaneously supplies a required amount of charge to the upper electrode immediately after or the like the first DC signal (bias signal) is supplied to the lower electrode. That is, the plasma stabilizing circuit 70 may suppress the plasma from being destabilized by allowing a sufficient transient current to flow to the upper electrode.

The first rectifying element D1 is placed in such a manner that the chamber 10 (upper electrode) side is in a forward direction of the current when viewed from the plasma stabilizing circuit 70.

In an embodiment, the first rectifying element D1 may be configured with a diode. In this case, a cathode electrode of the first rectifying element D1 (diode) may be electrically connected to the node N1. In addition, an anode electrode of the first rectifying element D1 (diode) may be electrically connected to the plasma stabilizing circuit 70. That is, the anode electrode of the first rectifying element D1 may be electrically connected to the ground potential via the capacitor C1 of the plasma stabilizing circuit 70. The diode may be, in an example, a mesa-type or planar-type PN junction diode. The first rectifying element D1 may be configured with multiple diodes, and in this case, the diodes may be connected to each other in series or in parallel.

A rectification operation of the first rectifying element D1 suppresses the second DC signal from the second DC generator 32b from flowing to the plasma stabilizing circuit 70. As a result, the voltage waveform of the second DC signal may be suppressed from being distorted by the large-capacity capacitor C1 of the plasma stabilizing circuit 70.

The first filter F1 is configured to filter a signal (hereinafter, referred to as an “RF signal”) in a frequency band of the source RF signal generated by the first RF generator 31a. That is, the first filter F1 blocks or attenuates the RF signal flowing from the chamber 10 (upper electrode) toward the first rectifying element D1. As a result, the entire or a part of the RF signal may be suppressed from passing through the first rectifying element D1 to heat the first rectifying element D1, and thus the rectification operation of the first rectifying element D1 may be suppressed from being reduced. In addition, the RF signal may be suppressed from entering the second DC generator 32b. When the first rectifying element D1 is placed on the input side (chamber 10 side) of the first filter F1, the attenuation performance of the first filter F1 may be affected when the impedance of the first rectifying element D1 is changed. In this regard, in the example illustrated in FIG. 5, the first rectifying element D1 is placed on the output side (second DC generator 32b side) of the first filter F1. Therefore, the attenuation performance of the first filter F1 may be suppressed from being affected by the change in the impedance of the first rectifying element D1.

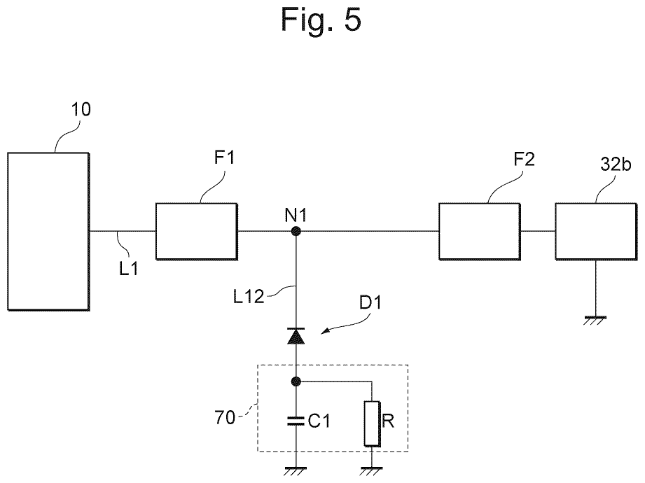

FIG. 6A is a diagram illustrating an example of the first filter F1. As illustrated in (a) to (d) of FIG. 6A, the first filter F1 may be configured to include one or multiple inductors (ID) and capacitors (C). The capacitance of the capacitor of the first filter F1 is sufficiently smaller than the capacitance of the capacitor C1 of the plasma stabilizing circuit 70, and is, in an example, 0.01 nF to 1 nF.

The second filter F2 is configured to filter a signal (hereinafter, referred to as a “bias pulse signal”) in a pulse frequency band of the first DC signal (bias signal) generated by the first DC generator 32a. That is, the second filter F2 blocks or attenuates the bias pulse signal flowing from the first rectifying element D1 toward the second DC generator 32b. As a result, the bias pulse signal may be suppressed from entering the second DC generator 32b. When the second filter F2 causes interference with the second DC signal, the second filter F2 may not be provided. For example, when the second DC signal has a frequency close to the pulse frequency of the first DC signal (for example, when the second DC signal has a frequency in ±10% of the pulse frequency of the first DC signal), the second filter F2 may not be provided.

FIG. 6B is a diagram illustrating an example of the second filter F2. As illustrated in (a) to (e) of FIG. 6B, the second filter F2 may be configured to include one or multiple inductors (ID) and capacitors (C). In an embodiment, the capacitance of the capacitor of the second filter F2 is sufficiently smaller than the capacitance of the capacitor C1 of the plasma stabilizing circuit 70, and is, in an example, 0.01 nF to 1 nF. In an embodiment, the capacitance of the capacitor of the second filter F2 may be the same as the capacitance of the capacitor C1 of the plasma stabilizing circuit 70 (in an example, 10 nF to 100 nF). In this case, a rectifying element may be provided in the second filter F2. The rectifying element may suppress the second DC signal from the second DC generator 32b from flowing into the capacitor of the second filter F2 and the waveform of the second DC signal from being distorted.

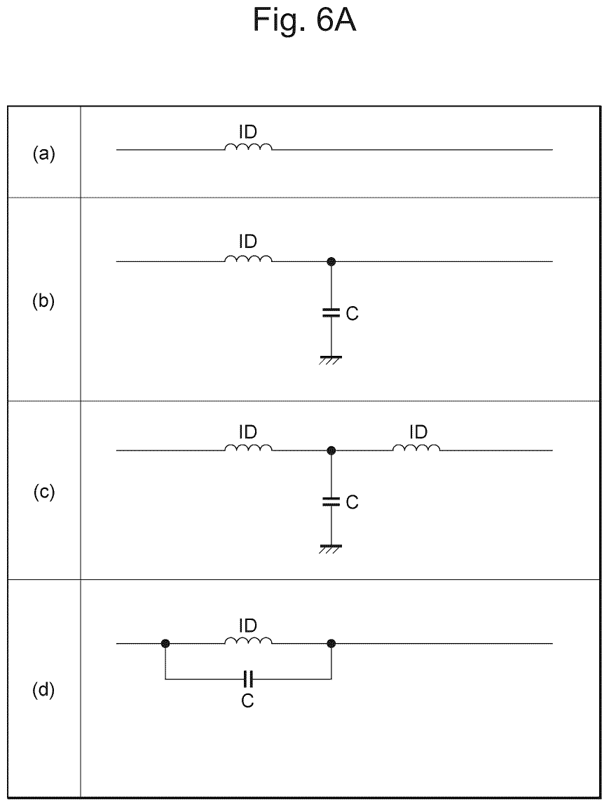

FIGS. 7A and 7B are diagrams illustrating another placement example of the node N1. As illustrated in FIG. 7A, the node N1 may be provided between the second filter F2 and the second DC generator 32b on the transmission line L1. In addition, as illustrated in FIG. 7B, the node N1 may be provided between the chamber 10 (upper electrode) and the first filter F1 on the transmission line L1. In the examples illustrated in FIGS. 7A and 7B, the first filter F1 and the second filter F2 may be integrally configured as one filter circuit.

In an embodiment, the position of the node N1 on the transmission line L1 may be appropriately set in such a manner that the current from the plasma stabilizing circuit 70 toward the upper electrode is not hindered. For example, when the first filter F1 has a relatively high inductance (for example, about 100 μH to 10,000 μH), the node N1 may be provided between the chamber 10 (upper electrode) and the first filter F1 (see FIG. 7B). As a result, the current from the plasma stabilizing circuit 70 toward the upper electrode is prevented from being hindered by the first filter F1. For example, when the first filter F1 has a relatively low inductance (for example, about 0.1 μH to 10 μH), the node N1 may be provided between the first filter F1 and the second filter F2 (see FIG. 5). In addition, in this case, the node N1 may be provided between the second filter F2 and the second DC generator 32b (see FIG. 7A). This is because the current from the plasma stabilizing circuit 70 toward the upper electrode is less likely to be hindered even when the first filter F1 or the second filter F2 is provided.

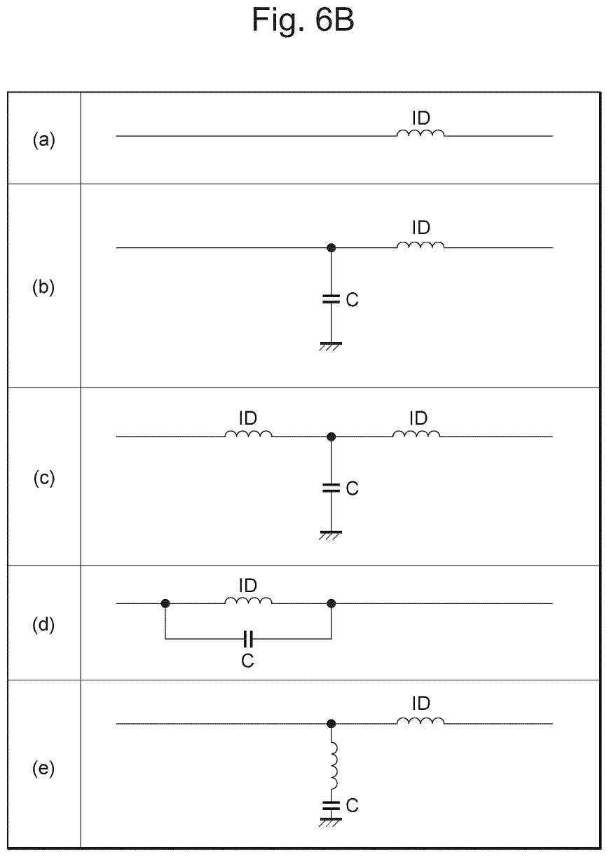

FIGS. 8A and 8B are diagrams for describing the operation of the plasma stabilizing circuit 70. FIG. 8A is an example of a case where the plasma stabilizing circuit 70 is not provided with respect to the upper electrode. FIG. 8B is an example of a case where the plasma stabilizing circuit 70 is provided with respect to the upper electrode. In FIGS. 8A and 8B, “DC1” indicates an example of a voltage waveform of the first DC signal supplied to the lower electrode, and “I” indicates an example of a current waveform of the transient current flowing through the upper electrode at this time.

As illustrated in FIG. 8A, when the plasma stabilizing circuit 70 is not provided, a peak (Ia) of the current waveform of the transient current in the upper electrode is suppressed. That is, a sufficient transient current does not flow through the upper electrode. This is because a sufficient charge is not supplied to the upper electrode. In this case, the plasma in the chamber 10 may be destabilized, and abnormal discharge or the like may occur. On the other hand, as illustrated in FIG. 8B, when the plasma stabilizing circuit is provided, a peak (Ib>Ia) of the transient current in the upper electrode is not suppressed. That is, a sufficient transient current flows through the upper electrode. This is because immediately after the first DC signal (bias signal) is supplied to the lower electrode, a charge is instantaneously supplied from the capacitor C1 of the plasma stabilizing circuit 70 to the upper electrode. As a result, the destabilization of the plasma in the chamber 10 may be suppressed.

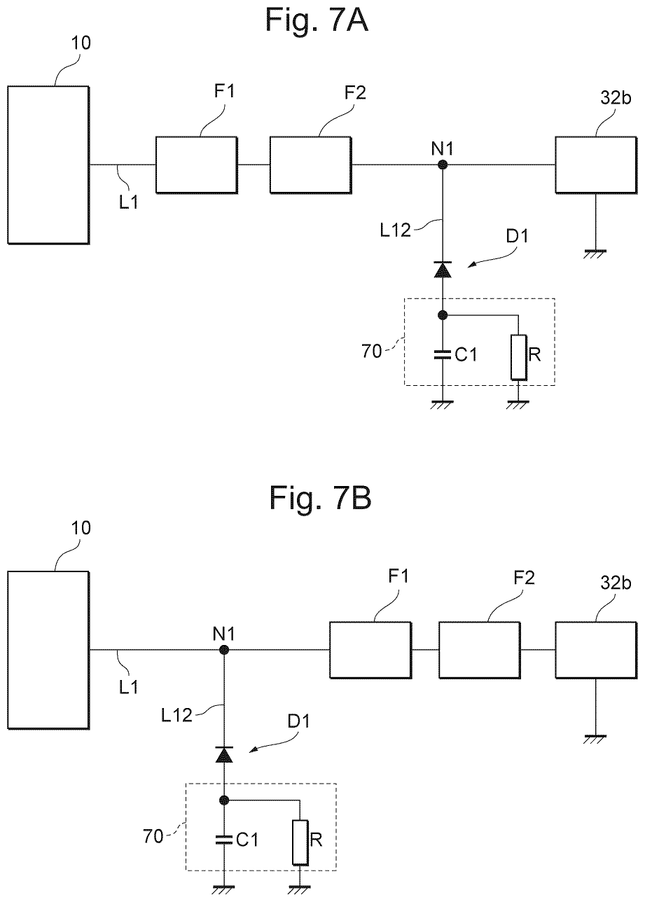

FIGS. 9A and 9B are diagrams for describing a rectification operation of the first rectifying element D1. FIG. 9A is an example of a case where the first rectifying element D1 is not provided in the transmission line L12. FIG. 9B is an example of a case where the first rectifying element D1 is provided in the transmission line L12. In FIGS. 9A and 9B, an upper part is an example of the voltage waveform of the second DC signal output from the second DC generator 32b. In FIGS. 9A and 9B, a lower part is an example of the voltage waveform of the second DC signal input to the upper electrode.

As illustrated in FIG. 9A, when the first rectifying element D1 is not provided, the voltage waveform of the second DC signal input to the upper electrode may be significantly distorted due to the influence of the large-capacity capacitor C1. On the other hand, as illustrated in FIG. 9B, when the first rectifying element D1 is provided, the influence of the large-capacity capacitor C1 is limited, and the distortion of the voltage waveform of the second DC signal input to the upper electrode may be suppressed.

### Second Embodiment

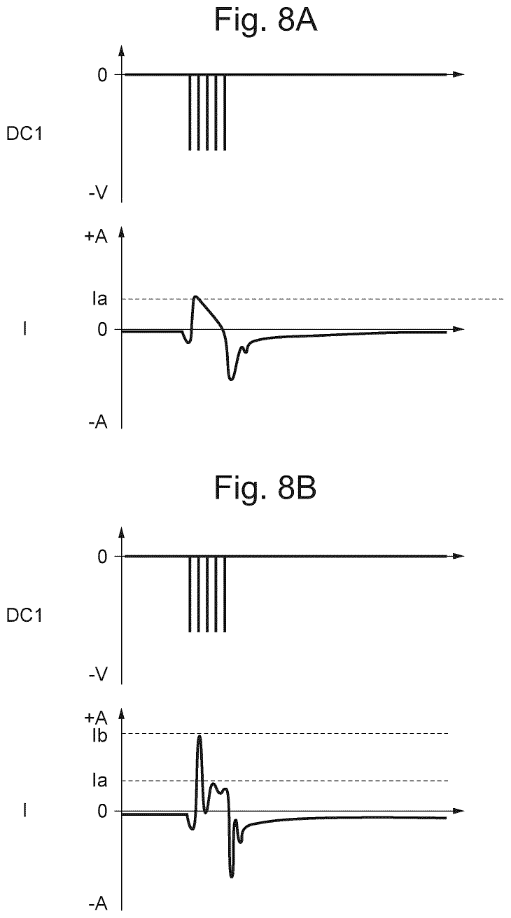

FIG. 10 is a diagram illustrating a configuration example of a plasma stabilizing circuit according to a second embodiment. The second embodiment is a configuration example of a case where a negative polarity first DC signal is supplied to the lower electrode. Hereinafter, configurations different from the first embodiment will be mainly described.

In the example illustrated in FIG. 10, the second waveform generator 50 is provided on the transmission line L1 between the node N1 and the second DC generator 32b. In an embodiment, the second DC signal generated by the second DC generator 32b has a negative polarity. The second waveform generator 50 is configured to pulse the second DC signal generated by the second DC generator 32b. The second DC signal output from the second waveform generator 50 may have a high-speed pulse as illustrated in FIG. 4A or FIG. 4B. In addition, the second DC signal output from the second waveform generator 50 may have a low-speed pulse as illustrated in FIG. 4C. In an embodiment, the second DC generator 32b may generate a positive second DC signal.

In the example illustrated in FIG. 10, the second filter F2 as illustrated in FIG. 5 is not provided. The second filter F2 may be provided when the interference with the second DC signal by the second filter F2 does not occur. For example, when the first DC signal has a high-speed pulse and the second DC signal has a low-speed pulse, the second filter F2 may be provided. In this case, the second filter F2 may be provided on the transmission line L1 between the first filter F1 and the second waveform generator 50.

In the second embodiment, the plasma stabilizing circuit 70 instantaneously supplies a required amount of charge to the upper electrode immediately after or the like the first DC signal (bias signal) is supplied to the lower electrode. As a result, a sufficient transient current flows to the upper electrode, and thus the plasma may be suppressed from being destabilized. In addition, the second DC signal output from the second waveform generator 50 does not flow to the plasma stabilizing circuit 70 due to the rectification operation of the first rectifying element D1. As a result, the voltage waveform of the second DC signal may be prevented from being distorted by the large-capacity capacitor C1 of the plasma stabilizing circuit 70.

### Second Rectifying Element

A voltage generated at the upper electrode by supplying the first DC signal (bias signal) to the lower electrode (hereinafter, also referred to as a “VDC voltage”) may cause control of the plasma by the second DC signal to become unstable. For example, when the voltage level of the VDC voltage in the upper electrode is higher than the voltage level of the second DC signal, a period may occur in which a current having a polarity opposite to the second DC signal flows to the upper electrode (that is, the current flows backward). While the current flows backward, the plasma cannot be controlled by the second DC signal, and the plasma in the chamber 10 may be destabilized. In order to suppress such a phenomenon, in an embodiment, a second rectifying element may be provided in the transmission line L1.

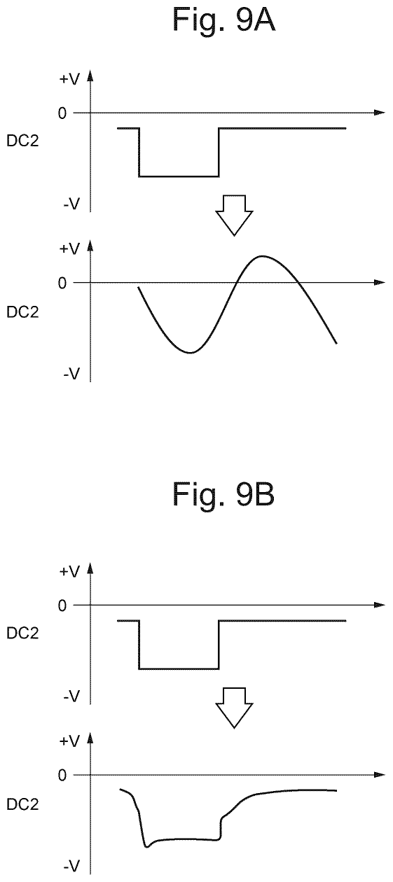

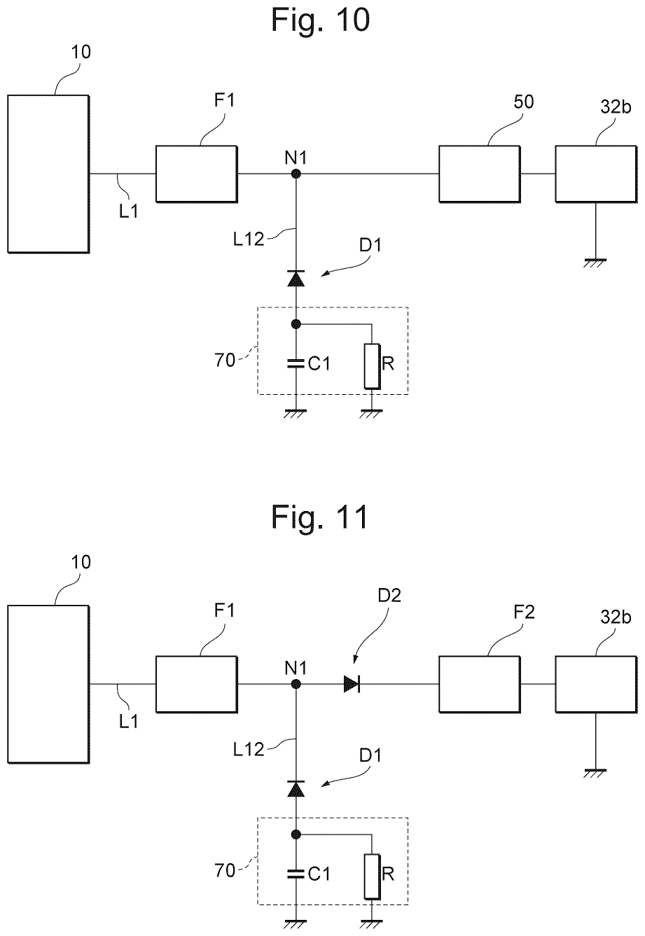

FIGS. 11 and 12 are diagrams illustrating an example of a second rectifying element D2. FIG. 11 is an example in which the second rectifying element D2 is provided in the configuration according to the first embodiment illustrated in FIG. 5. FIG. 12 is an example in which the second rectifying element D2 is provided in the configuration according to the second embodiment illustrated in FIG. 10. The second rectifying element D2 may be provided between the node N1 and the second filter F2 in the transmission line L1 (see FIG. 11), or may be provided between the node N1 and the second waveform generator 50 (see FIG. 12).

The second rectifying element is configured to block or suppress the current having the polarity opposite to the second DC signal generated by the second DC generator 32b. For example, in the examples illustrated in FIGS. 11 and 12, when the second DC signal has a negative polarity, the second rectifying element D2 may be configured to block or suppress the current flowing through the transmission line L1 from the second DC generator 32b or the second waveform generator 50 toward the node N1 side.

In an embodiment, the second rectifying element D2 may be configured with a diode. In this case, an anode electrode of the second rectifying element D2 (diode) may be electrically connected to the chamber 10 (upper electrode). In addition, a cathode electrode of the second rectifying element D2 (diode) may be electrically connected to the second DC generator 32b or the second waveform generator 50. The diode may be, in an example, a mesa-type or planar-type PN junction diode. The second rectifying element D2 may be configured with multiple diodes, and in this case, the diodes may be connected to each other in series or in parallel.

The second rectifying element D2 may block or suppress the current flowing backward through the transmission line L1 from the second DC generator 32b toward the node N1 side. Therefore, the control of the plasma by the second DC signal is prevented from being unstable. As a result, the occurrence of abnormal discharge or the like due to the instability of the plasma in the chamber 10 may be prevented.

### Third Embodiment

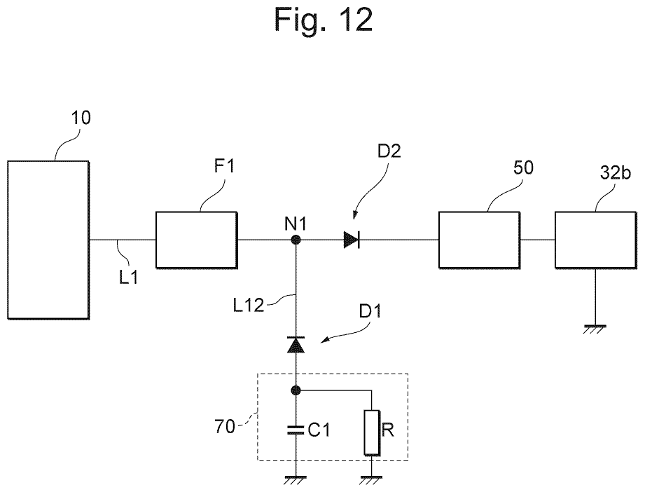

FIG. 13 is a diagram illustrating another coupling example between the power supply 30 and the chamber 10 of the plasma processing apparatus 1. In the example illustrated in FIG. 13, an impedance fixing circuit 60 is connected to the upper electrode via a transmission line L4 instead of the second DC generator 32b.

The impedance fixing circuit 60 is a circuit used to define the impedance of the upper electrode. The impedance fixing circuit may be configured by connecting an inductor and/or a capacitor in series or in parallel in such a manner that the impedance fixing circuit has any impedance at any frequency. In an embodiment, the impedance fixing circuit 60 may be configured in the same manner as the first filter or the second filter illustrated in FIGS. 6A and 6B.

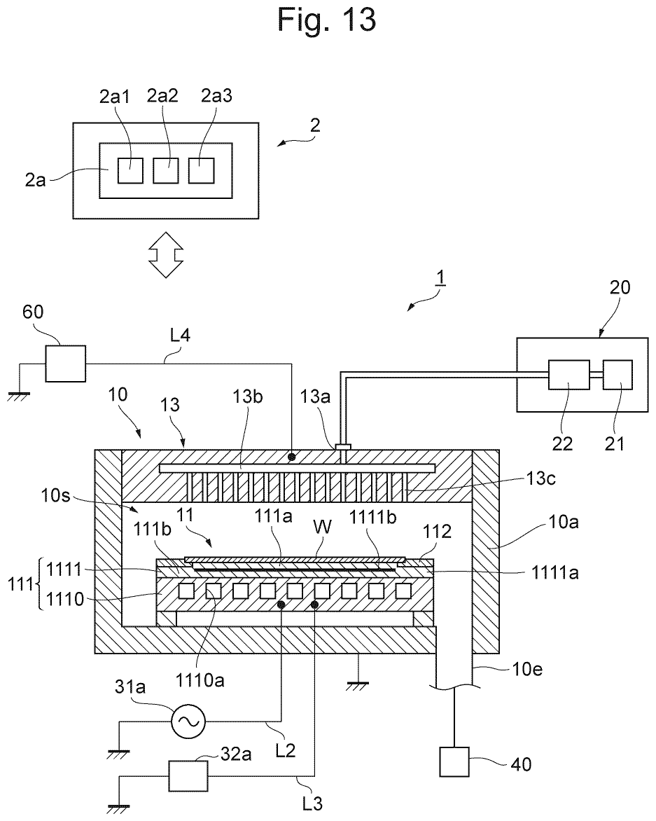

FIG. 14 is a diagram illustrating a configuration example of a plasma stabilizing circuit according to a third embodiment. The third embodiment is a configuration example of a case where a negative polarity first DC signal is supplied to the lower electrode. As illustrated in FIG. 14, a node N2 is provided between the chamber 10 (upper electrode) and the impedance fixing circuit 60. As in the first embodiment and the second embodiment described above, the first rectifying element D1 and the plasma stabilizing circuit 70 are provided on a transmission line L42 between the node N2 and the ground potential.

In the third embodiment, the plasma stabilizing circuit 70 instantaneously supplies a required amount of charge to the upper electrode immediately after or the like the first DC signal (bias signal) is supplied to the lower electrode. That is, the plasma stabilizing circuit 70 may suppress the plasma from being destabilized by allowing a sufficient transient current to flow to the upper electrode.

The capacitor C1 of the plasma stabilizing circuit 70 has a low impedance. Therefore, the capacitor C1 may strongly affect the impedance of the impedance fixing circuit 60 as viewed from the chamber 10 (upper electrode) side when the first rectifying element D1 is not provided. In the third embodiment, the first rectifying element D1 is provided on the transmission line L42 between the node N2 and the plasma stabilizing circuit 70. The first rectifying element D1 functions as a high impedance element. Therefore, the capacitor C1 may be suppressed from affecting the impedance of the impedance fixing circuit 60 as viewed from the chamber 10 (upper electrode) side.

### Modification Examples

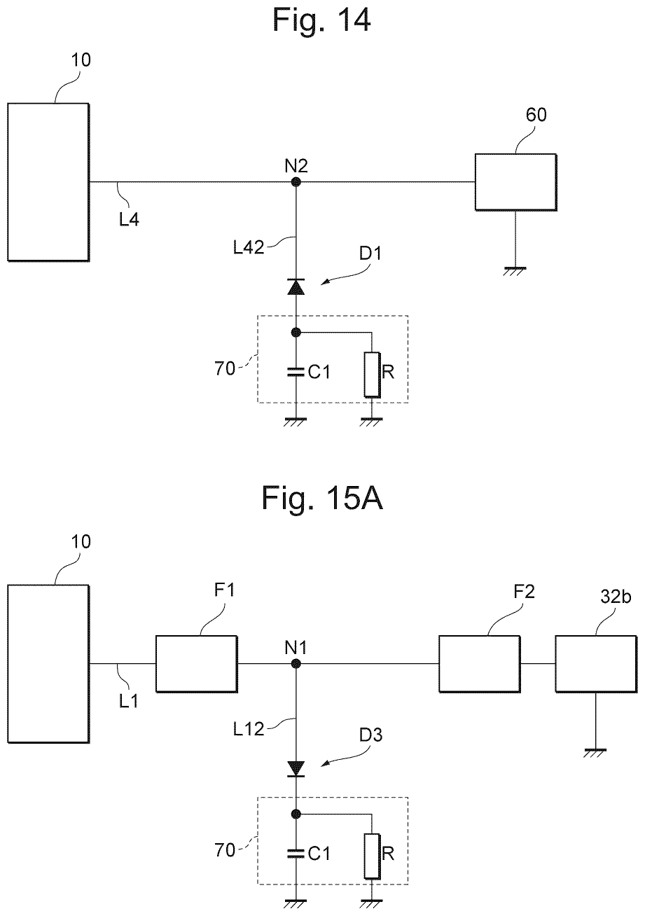

FIG. 15A is a diagram illustrating a modification example of the first embodiment (FIG. 5). FIG. 15B is a diagram illustrating a modification example of the second embodiment (FIG. 10). These examples are configuration examples of a case where the first DC signal generated by the first DC generator 32a has a positive polarity. The second DC signal generated by the second DC generator 32b may have a positive polarity or a negative polarity.

As illustrated in FIGS. 15A and 15B, a third rectifying element D3 is provided on the transmission line L12. The third rectifying element D3 is placed in such a manner that the rectification direction is opposite to the rectification direction of the first rectifying element D1, that is, the chamber 10 (upper electrode) side is in the opposite direction of the current as viewed from the plasma stabilizing circuit 70. The third rectifying element D3 may be configured in the same manner as the first rectifying element D1, except that the rectification direction is opposite.

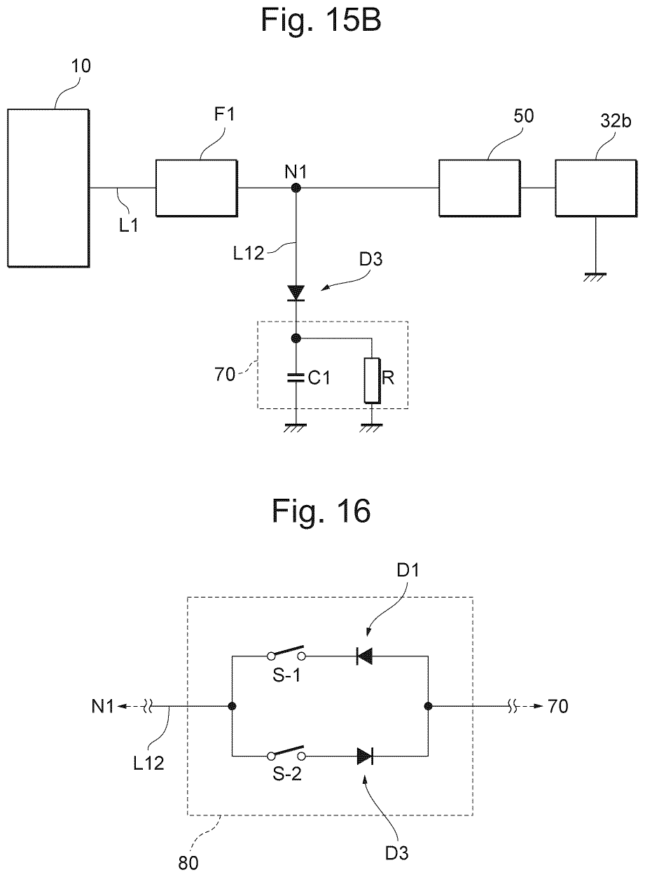

FIG. 16 is a diagram illustrating an example of a polarity switching circuit. As illustrated in FIG. 16, a polarity switching circuit 80 may be provided on the transmission line L12. The polarity switching circuit 80 is configured to switch the first rectifying element D1 and the third rectifying element D3 at a given timing. For example, when the polarity of the first DC signal is reversed during the process, the polarity switching circuit 80 may switch the first rectifying element D1 and the third rectifying element D3. Specifically, when the first DC signal generated by the first DC generator 32a has a negative polarity, the polarity switching circuit 80 may turn on a switching element S-1 and turn off a switching element S-2 to enable the first rectifying element D1. In an example, when the first DC signal generated by the first DC generator 32a has a positive polarity, the polarity switching circuit 80 may turn off the switching element S-1 and turn on the switching element S-2 to enable the third rectifying element D3.

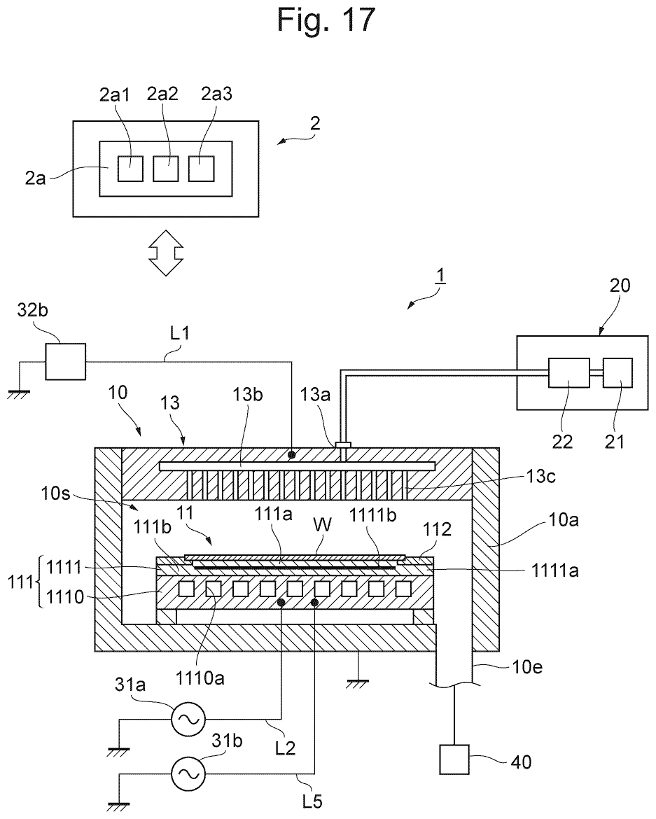

FIG. 17 is a diagram illustrating another coupling example between the power supply 30 and the chamber 10. In the example illustrated in FIG. 17, the second RF generator 31b is electrically connected to the lower electrode via a transmission line L5. That is, the bias RF signal may be supplied to the lower electrode as the bias signal. The other points may be the same as the example illustrated in FIG. 3. As in the first embodiment and the second embodiment, the plasma stabilizing circuit 70 or the like may be electrically connected to the upper electrode via the node N1 of the transmission line L1.

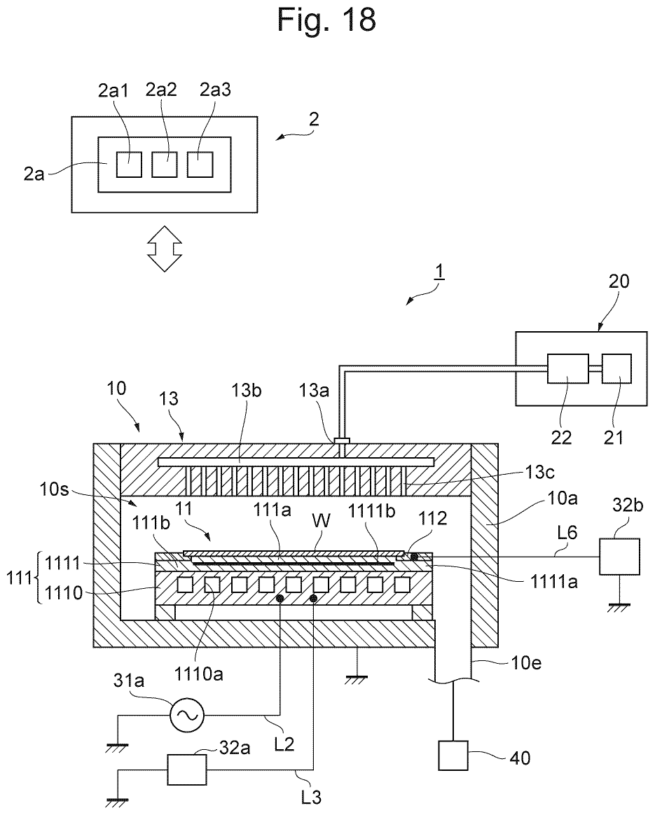

FIG. 18 is a diagram illustrating another coupling example between the power supply 30 and the chamber 10. The example illustrated in FIG. 18 is an example in which the second DC generator 32b is electrically connected to the ring assembly 112 via the transmission line L6. That is, the second DC signal may be supplied to the ring assembly 112. The other points may be the same as the example illustrated in FIG. 3. As in the first embodiment and the second embodiment, the plasma stabilizing circuit 70 or the like may be electrically connected to the ring assembly 112 via the node of the transmission line L6.

As illustrated in FIG. 18, in an embodiment, the second DC generator 32b may be electrically connected to a conductive member other than the upper electrode. The conductive member may be placed in the chamber 10 and may constitute a part of the chamber 10 as long as the conductive member is other than the ground electrode (including a conductive path to the ground electrode). For example, the conductive member may be a ring-shaped electrode placed to be spaced apart from the ring assembly 112 on the inner side or the outer side in the radial direction, in addition to the ring assembly 112 described above. In addition, for example, the conductive member may be an inner wall of the chamber 10, a liner placed along the inner wall, or a baffle plate placed to surround the substrate support 11. As in the first embodiment and the second embodiment, the plasma stabilizing circuit 70 or the like may be electrically connected to the node between the second DC generator 32b and the conductive member.

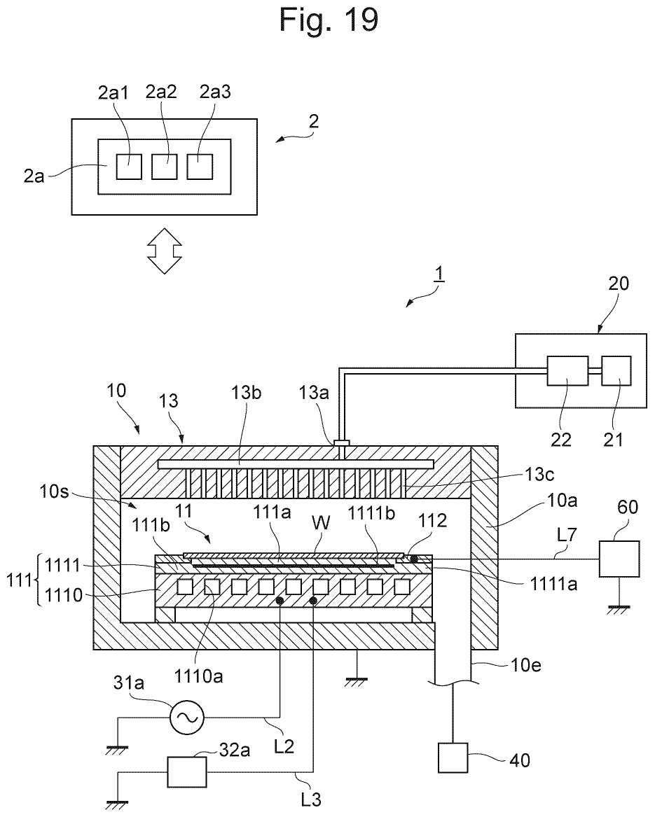

FIG. 19 is a diagram illustrating another coupling example between the power supply 30 and the chamber 10. FIG. 19 is a modification example of the configuration illustrated in FIG. 18. In this example, the impedance fixing circuit 60 is electrically connected to the ring assembly 112 instead of the second DC generator 32b. As in the third embodiment, the plasma stabilizing circuit 70 or the like may be electrically connected to the ring assembly 112 via the node of the transmission line L7.

As illustrated in FIG. 19, in an embodiment, the impedance fixing circuit 60 may be electrically connected to a conductive member other than the upper electrode. The conductive member may be placed in the chamber 10 and may constitute a part of the chamber 10 as long as the conductive member is a non-grounded electrode. The conductive member may be a ring-shaped electrode placed to be spaced apart from the ring assembly 112 on the inner side or the outer side in the radial direction, in addition to the ring assembly 112 described above. In addition, for example, the conductive member may be the inner wall of the chamber 10, the liner placed along the inner wall, or the baffle plate placed to surround the substrate support 11. As in the third embodiment, the plasma stabilizing circuit 70 or the like may be electrically connected to the node between the impedance fixing circuit 60 and the conductive member.

The embodiments of the present disclosure further include the following aspects.

### Aspect 1

A plasma processing apparatus including:
a chamber;
a substrate support disposed in the chamber and including at least one lower electrode;
an upper electrode disposed above the substrate support;
an RF signal generator electrically connected to the at least one lower electrode or the upper electrode, and configured to generate an RF signal for generating a plasma in the chamber;
a first voltage signal generator electrically connected to any of the at least one lower electrode and configured to generate a first voltage signal, the first voltage signal having a sequence of first voltage pulses;
a second voltage signal generator electrically connected to the upper electrode and configured to generate a second voltage signal;
a capacitor; and
a rectifying element including a first electrode and a second electrode, the first electrode being electrically connected to a node between the upper electrode and the second voltage signal generator, and the second electrode being electrically connected to a ground potential via the capacitor.

### Aspect 2

The plasma processing apparatus according to Aspect 1, in which the second voltage signal has a sequence of second voltage pulses.

### Aspect 3

The plasma processing apparatus according to Aspect 1, in which the second voltage signal has a constant voltage level.

### Aspect 4

The plasma processing apparatus according to Aspect 2, in which the second voltage signal has a negative polarity, the first electrode is a cathode electrode, and the second electrode is an anode electrode.

### Aspect 5

The plasma processing apparatus according to Aspect 4, in which the sequence of the first voltage pulses has a first pulse frequency in a range of 0.1 MHz to 2 MHz.

### Aspect 6

The plasma processing apparatus according to Aspect 4 or 5, in which the sequence of the second voltage pulses has a second pulse frequency in a range of 0.1 kHz to 50 kHz.

### Aspect 7

The plasma processing apparatus according to any one of Aspects 1 to 6, further including: a filter circuit provided in a transmission line between the upper electrode and the second voltage signal generator.

### Aspect 8

The plasma processing apparatus according to any one of Aspects 1 to 7, further including: a filter circuit provided in a transmission line between the upper electrode and the node.

### Aspect 9

The plasma processing apparatus according to any one of Aspects 1 to 8, further including: a filter circuit provided in a transmission line between the node and the second voltage signal generator.

### Aspect 10

The plasma processing apparatus according to any one of Aspects 1 to 9, further including:
a first filter provided in a transmission line between the upper electrode and the node, and configured to filter a signal in a band of an RF frequency of the RF signal; and
a second filter provided in a transmission line between the node and the second voltage signal generator, and configured to filter a signal in a band of a pulse frequency of the sequence of the first voltage pulses.

### Aspect 11

A plasma processing apparatus including:
a chamber;
a substrate support disposed in the chamber and including at least one lower electrode;
an upper electrode disposed above the substrate support;
an RF signal generator electrically connected to the at least one lower electrode or the upper electrode, and configured to generate an RF signal for generating a plasma in the chamber;
a voltage signal generator electrically connected to the at least one lower electrode and configured to generate a voltage signal, the voltage signal having a sequence of voltage pulses;
an impedance fixing circuit electrically connected to the upper electrode;
a capacitor; and
a rectifying element including a first electrode and a second electrode, the first electrode being electrically connected to a node between the upper electrode and the impedance fixing circuit, and the second electrode being electrically connected to a ground potential via the capacitor.

### Aspect 12

The plasma processing apparatus according to Aspect 11, in which the voltage pulses have a negative polarity, the first electrode is a cathode electrode, and the second electrode is an anode electrode.

### Aspect 13

The plasma processing apparatus according to Aspect 11 or 12, in which the sequence of the voltage pulses has a first pulse frequency in a range of 0.1 MHz to 2 MHz.

### Aspect 14

The plasma processing apparatus according to any one of Aspects 11 to 13, in which the impedance fixing circuit includes at least one of a capacitor and an inductor.

### Aspect 15

A plasma processing apparatus including:
a chamber;
a substrate support disposed in the chamber and including an electrode;
a first voltage signal generator electrically connected to the electrode, and configured to generate a first voltage signal, the first voltage signal having a sequence of first voltage pulses;
a conductive member constituting a part of the chamber or disposed in the chamber;
a capacitor; and
a rectifying element including a first electrode and a second electrode, the first electrode being electrically connected to the conductive member and the second electrode being electrically connected to a ground potential via the capacitor.

### Aspect 16

The plasma processing apparatus according to Aspect 15, further including: a second voltage signal generator electrically connected to a node between the conductive member and the first electrode of the rectifying element, and configured to generate a second voltage signal.

### Aspect 17

The plasma processing apparatus according to Aspect 16, wherein the second voltage signal has a negative polarity, the first electrode is a cathode electrode, and the second electrode is an anode electrode.

### Aspect 18

The plasma processing apparatus according to Aspect 15, further including: an impedance fixing circuit electrically connected to a node between the conductive member and the first electrode of the rectifying element.

### Aspect 19

The plasma processing apparatus according to Aspect 18, in which the impedance fixing circuit includes at least one of a capacitor and an inductor.

### Aspect 20

The plasma processing apparatus according to any one of Aspects 15 to 18, in which the conductive member is any one of
(a) an upper electrode disposed above the substrate support,
(b) a ring assembly disposed on the substrate support to surround a substrate on the substrate support,
(c) a liner disposed along an inner wall of the chamber, and
(d) a baffle plate disposed to surround the substrate support.

Each of the above-described embodiments is described for the purpose of description, and it is not intended to limit the scope of the present disclosure. Each of the above-described embodiments may be modified in various ways without departing from the scope and gist of the present disclosure. For example, some configuration elements in one embodiment can be added to other embodiments. In addition, some configuration elements in one embodiment can be replaced with corresponding configuration elements in another embodiment.

What is claimed is:

1. A plasma processing apparatus comprising:
a chamber;
a substrate support disposed in the chamber and including at least one lower electrode;
an upper electrode disposed above the substrate support;
an RF signal generator electrically connected to the at least one lower electrode or the upper electrode, and configured to generate an RF signal for generating a plasma in the chamber;
a first voltage signal generator electrically connected to the at least one lower electrode and configured to generate a first voltage signal, the first voltage signal having a sequence of first voltage pulses;
a second voltage signal generator electrically connected to the upper electrode and configured to generate a second voltage signal;
a capacitor; and
a rectifying element including a first electrode and a second electrode, the first electrode being electrically connected to a node between the upper electrode and the second voltage signal generator, and the second electrode being electrically connected to a ground potential via the capacitor.

2. The plasma processing apparatus according to claim 1, wherein the second voltage signal has a sequence of second voltage pulses.

3. The plasma processing apparatus according to claim 1, wherein the second voltage signal has a constant voltage level.

4. The plasma processing apparatus according to claim 2, wherein the second voltage signal has a negative polarity, the first electrode is a cathode electrode, and the second electrode is an anode electrode.

5. The plasma processing apparatus according to claim 4, wherein the sequence of the first voltage pulses has a first pulse frequency in a range of 0.1 MHz to 2 MHz.

6. The plasma processing apparatus according to claim 5, wherein the sequence of the second voltage pulses has a second pulse frequency in a range of 0.1 kHz to 50 kHz.

7. The plasma processing apparatus according to claim 1, further comprising:
a filter circuit provided in a transmission line between the upper electrode and the second voltage signal generator.

8. The plasma processing apparatus according to claim 1, further comprising:
a filter circuit provided in a transmission line between the upper electrode and the node.

9. The plasma processing apparatus according to claim 1, further comprising:
a filter circuit provided in a transmission line between the node and the second voltage signal generator.

10. The plasma processing apparatus according to claim 1, further comprising:
a first filter provided in a transmission line between the upper electrode and the node, and configured to filter a signal in a band of an RF frequency of the RF signal; and
a second filter provided in a transmission line between the node and the second voltage signal generator, and configured to filter a signal in a band of a pulse frequency of the sequence of the first voltage pulses.

11. A plasma processing apparatus comprising:
a chamber;
a substrate support disposed in the chamber and including at least one lower electrode;
an upper electrode disposed above the substrate support;
an RF signal generator electrically connected to the at least one lower electrode or the upper electrode, and configured to generate an RF signal for generating a plasma in the chamber;
a voltage signal generator electrically connected to the at least one lower electrode and configured to generate a voltage signal, the voltage signal having a sequence of voltage pulses;
an impedance fixing circuit electrically connected to the upper electrode;
a capacitor; and
a rectifying element including a first electrode and a second electrode, the first electrode being electrically connected to a node between the upper electrode and the impedance fixing circuit, and the second electrode being electrically connected to a ground potential via the capacitor.

12. The plasma processing apparatus according to claim 11, wherein the voltage pulses have a negative polarity, the first electrode is a cathode electrode, and the second electrode is an anode electrode.

13. The plasma processing apparatus according to claim 12, wherein the sequence of the voltage pulses has a first pulse frequency in a range of 0.1 MHz to 2 MHz.

14. The plasma processing apparatus according to claim 13, wherein the impedance fixing circuit includes at least one of a capacitor and an inductor.

15. A plasma processing apparatus comprising:
a chamber;
a substrate support disposed in the chamber and including an electrode;
a first voltage signal generator electrically connected to the electrode, and configured to generate a first voltage signal, the first voltage signal having a sequence of first voltage pulses;
a conductive member constituting a part of the chamber or disposed in the chamber;
a capacitor; and
a rectifying element including a first electrode and a second electrode, the first electrode being electrically connected to the conductive member and the second electrode being electrically connected to a ground potential via the capacitor.

16. The plasma processing apparatus according to claim 15, further comprising:
a second voltage signal generator electrically connected to a node between the conductive member and the first electrode of the rectifying element, and configured to generate a second voltage signal.

17. The plasma processing apparatus according to claim 16, wherein the second voltage signal has a negative polarity, the first electrode is a cathode electrode, and the second electrode is an anode electrode.

18. The plasma processing apparatus according to claim 15, further comprising:
an impedance fixing circuit electrically connected to a node between the conductive member and the first electrode of the rectifying element.

19. The plasma processing apparatus according to claim 18, wherein the impedance fixing circuit includes at least one of a capacitor and an inductor.

20. The plasma processing apparatus according to claim 15, wherein the conductive member is any one of
(a) an upper electrode disposed above the substrate support,
(b) a ring assembly disposed on the substrate support to surround a substrate on the substrate support,
(c) a liner disposed along an inner wall of the chamber, and
(d) a baffle plate disposed to surround the substrate support.
